(19) United States
(12) Patent Application Publication
(10) Pub. No.: US 2024/0256742 A1
(43) Pub. Date: Aug. 1, 2024

(54) MACHINE LEARNING CLASSIFICATION AND REDUCTION OF cad PARTS FOR RAPID DESIGN TO SIMULATION

(71) Applicant: National Technology & Engineering Solutions of Sandia, LLC, Albuquerque, NM (US)

(72) Inventors: Steven J. Owen, Carlsbad, CA (US); Armida J. Carbajal, Albuquerque, NM (US); Corey Devan Ernst, American Fork, UT (US); Matthew Gregor Peterson, Albuquerque, NM (US)

(21) Appl. No.: 18/484,143

(22) Filed: Oct. 10, 2023

Related U.S. Application Data
(60) Provisional application No. 63/442,543, filed on Feb. 1, 2023.

(51) Int. Cl. G06F 30/27; G06F 30/10

(52) U.S. Cl. CPC G06F 30/27; G06F 30/10

(57) ABSTRACT

A computer-implemented method of machine learning classification for Computer Assisted Design (CAD) is provided. The method comprises receiving a number of CAD volumes comprising a dataset, wherein each CAD volume is characterized by a number of scalar values corresponding to features of the CAD volume, wherein the features rely on geometry queries from a CAD kernel. Each CAD volume is labeled with part names according to a set of categories defined by a user, and a machine learning model is trained with the features of the labeled CAD volumes.

### CROSS-REFERENCE TO RELATED APPLICATION

This application claims priority to U.S. Provisional Application 63/442,543, filed Feb. 1, 2023, the entirety of which is hereby incorporated by reference.

### STATEMENT OF GOVERNMENT INTEREST

This invention was made with United States Government support under Contract No. DE-NA0003525 between National Technology & Engineering Solutions of Sandia, LLC and the United States Department of Energy. The United States Government has certain rights in this invention.

### BACKGROUND

### 1. Field

The disclosure relates generally to computer aided design (CAD), and more specifically to using machine learning to distinguish categories of mechanisms within complex CAD assemblies.

### 2. Description of the Related Art

Computer-aided modelling or computer-aided design (CAD) creates virtual models of objects or systems, which allows engineers and designers to visualize and simulate structures or processes. Complex assemblies frequently include many common mechanisms such as bolts, screws, springs, gears, bearings, etc. In practice, analysts spend extensive time identifying and then transforming each mechanism to prepare for analysis. For example, bolted connections might require specific geometric simplifications, specialized meshing, and boundary condition assignment. For an assembly with hundreds of bolts, model preparation can be tedious and error prone.

Therefore, it would be desirable to have a method and apparatus that take into account at least some of the issues discussed above, as well as other possible issues.

### SUMMARY

An illustrative embodiment provides a computer-implemented method of machine learning classification for Computer Assisted Design (CAD). The method comprises receiving a number of CAD volumes comprising a dataset, wherein each CAD volume is characterized by a number of scalar values corresponding to features of the CAD volume, wherein the features rely on geometry queries from a CAD kernel. Each CAD volume is labeled with part names according to a set of categories defined by a user, and a machine learning model is trained with the features of the labeled CAD volumes.

Another illustrative embodiment provides a system for machine learning classification for Computer Assisted Design (CAD). The system comprises a storage device that stores program instructions and one or more processors operably connected to the storage device and configured to execute the program instructions to cause the system to: receive a number of CAD volumes comprising a dataset, wherein each CAD volume is characterized by a number of scalar values corresponding to features of the CAD volume, wherein the features rely on geometry queries from a CAD kernel; label each CAD volume with part names according to a set of categories defined by a user; and train a machine learning model with the features of the labeled CAD volumes.

Another illustrative embodiment provides a computer program product for machine learning classification for Computer Assisted Design (CAD). The computer program product comprises a computer-readable storage medium having program instructions embodied thereon to perform the steps of: receiving a number of CAD volumes comprising a dataset, wherein each CAD volume is characterized by a number of scalar values corresponding to features of the CAD volume, wherein the features rely on geometry queries from a CAD kernel; labeling each CAD volume with part names according to a set of categories defined by a user; and training a machine learning model with the features of the labeled CAD volumes.

The features and functions can be achieved independently in various examples of the present disclosure or may be combined in yet other examples in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 depicts a block diagram of a CAD classification system in accordance with an illustrative embodiment;

FIG. 2 depicts an diagram illustrating the environment for grouping volumes of a CAD assembly in real time using a classification procedure in accordance with an illustrative embodiment;

FIG. 3 illustrates examples of CAD parts used to develop ground truth for mechanism classification in accordance with an illustrative embodiment;

FIG. 4 depicts a diagram illustrating the classification problem solved by the machine learning process in accordance with an illustrative embodiment;

FIG. 5 depicts an example of a graphical user interface with classification options in accordance with an illustrative embodiment;

FIG. 6 depicts an example graphical user interface showing classification results in accordance with an illustrative embodiment;

FIG. 7 depicts a flowchart illustrating a process of neural network prediction correction in accordance with an illustrative embodiment;

FIG. 8A illustrates an initial bolt solid model in context with its surrounding volumes in accordance with an illustrative embodiment;

FIG. 8B illustrates a reduced bolt geometry ready for analysis in accordance with an illustrative embodiment;

FIG. 9 depicts a flowchart illustrating an algorithm to reduce one or more bolts in accordance with an illustrative embodiment;

FIG. 10A illustrates an initial spring solid model in accordance with an illustrative embodiment;

FIG. 10B illustrates a reduced, beam representation of the spring ready for analysis in accordance with an illustrative embodiment;

FIG. 11 depicts a flowchart illustrating an algorithm to reduce one or more springs in accordance with an illustrative embodiment;

FIG. 12 depicts a diagram of a schema for in-situ classification in accordance with an illustrative embodiment; and

FIG. 13 is a diagram of a data processing system depicted in accordance with an illustrative embodiment.

### DETAILED DESCRIPTION

The illustrative embodiments recognize and take into account that in CAD models complex assemblies frequently include many common mechanisms such as bolts, screws, springs, gears, bearings, etc. In practice, analysts spend extensive time identifying and then transforming each mechanism to prepare for analysis. Engineering analysists often obtain the CAD assembly in the form of a STEP (Standard for the Exchange of Product Data) file to develop a detailed 3D representation.

The illustrative embodiments also recognize and take into account that this representation, while usually accurate for manufacturing purposes, is rarely in a form that is directly suitable for simulation. As a consequence, the engineering analyst must become thoroughly familiar with each component of the assembly and its intended function within the assembly so they may accurately represent it in the simulation tool.

The illustrative embodiments also recognize and take into account that machine learning (ML)-based part classification is often used for rapid sorting of mechanisms for industrial manufacturing processes. Recent work that has demonstrated machine learning methods useful for shape recognition and classification of CAD models include references. Unfortunately, these methods stop short of driving modifications to the CAD model such as those required for mesh generation and simulation.

The illustrative embodiments provide a machine learning approach to streamline the process of converting CAD models for Finite Element Analysis (FEA) simulations, a critical step in many engineering workflows. The illustrative embodiments identify and classify common mechanisms such as fasteners and springs, which require specific simplification and preparation procedures. To extract features from CAD parts, the illustrative embodiments introduce a novel topology-based method that utilizes geometry queries from a third party CAD kernel. Using supervised learning, the illustrative embodiments develop a classification procedure that accurately predicts the categorization of the parts from a pre-defined set of categories. The illustrative embodiments outperform existing approaches in the literature. Additionally, the illustrative embodiments provide several reduction operations to transform CAD parts that are classified as fasteners and springs into simulation-ready proxies efficiently.

The illustrative embodiments also introduce an in-situ classification tool that enables custom categorization and easy integration of user-defined training data. This tool serves as a foundation for creating a shared knowledge base of categorized parts within a community of analysts.

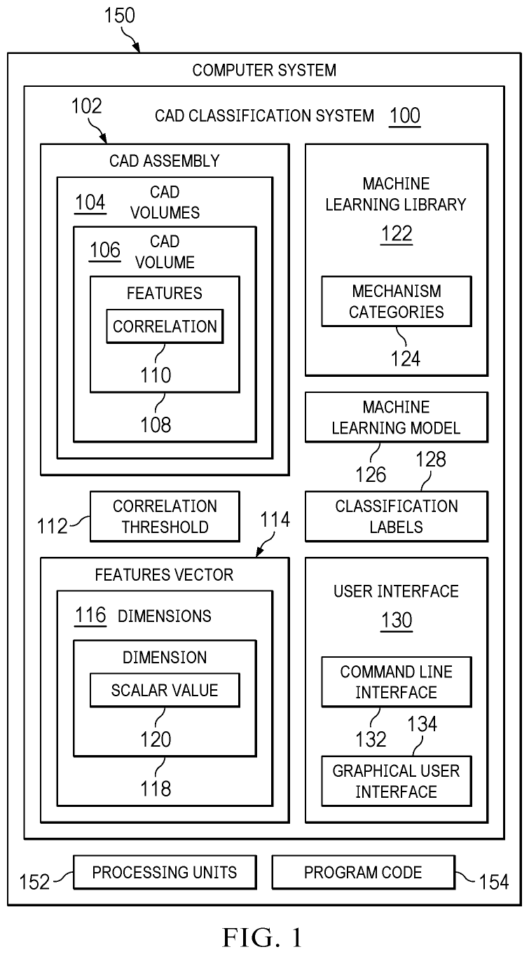

FIG. 1 depicts a block diagram of a CAD classification system in accordance with an illustrative embodiment. CAD classification system 100 provides classification labels 128 for a number of CAD volumes 104 that comprise a CAD assembly 102. Each CAD volume 106 comprises a number of features 108.

A CAD volume 106 can be represented by a features vector 114 comprising a number of dimensions 116 that correspond to the features 108 of the CAD volume 106 in question. Each dimension 118 in the features vector 114 has a corresponding scalar value 120.

The features vector 114 is fed into a machine learning model 126 that generates a classification label 128 for the CAD volume according to mechanism categories 124 contained in a machine learning library 122. To reduce the number of mechanism categories 124 in machine learning library 122 used by machine learning model 126 to classify a CAD volume, CAD classification system 100 may remove features from consideration that have a correlation 110 above a specified correlation threshold 112.

A user can input CAD assembly 102 as well as data related to mechanism categories 124 and receive out of the classification labels via user interface 130. User interface 130 might comprise a command line interface 132 and/or a graphical user interface 134.

In the illustrative examples, the hardware can take a form selected from at least one of a circuit system, an integrated circuit, an application specific integrated circuit (ASIC), a programmable logic device, or some other suitable type of hardware configured to perform a number of operations. With a programmable logic device, the device can be configured to perform the number of operations. The device can be reconfigured at a later time or can be permanently configured to perform the number of operations. Programmable logic devices include, for example, a programmable logic array, a programmable array logic, a field programmable logic array, a field programmable gate array, and other suitable hardware devices. Additionally, the processes can be implemented in organic components integrated with inorganic components and can be comprised entirely of organic components excluding a human being. For example, the processes can be implemented as circuits in organic semiconductors.

Computer system 150 is a physical hardware system and includes one or more data processing systems. When more than one data processing system is present in computer system 150, those data processing systems are in communication with each other using a communications medium. The communications medium can be a network. The data processing systems can be selected from at least one of a computer, a server computer, a tablet computer, or some other suitable data processing system.

As depicted, computer system 150 includes a number of processor units 152 that are capable of executing program code 154 implementing processes in the illustrative examples. As used herein, a processor unit in the number of processor units 152 is a hardware device and is comprised of hardware circuits such as those on an integrated circuit that respond and process instructions and program code that operate a computer. When a number of processor units 152 execute program code 154 for a process, the number of processor units 152 is one or more processor units that can be on the same computer or on different computers. In other words, the process can be distributed between processor units on the same or different computers in a computer system. Further, the number of processor units 152 can be of the same type or different type of processor units. For example, a number of processor units can be selected from at least one of a single core processor, a dual-core processor, a multi-processor core, a general-purpose central processing unit (CPU), a graphics processing unit (GPU), a digital signal processor (DSP), or some other type of processor unit.

The illustrative embodiments address critical bottlenecks in the CAD-to-simulation process. In particular, the illustrative processes focus on the problem of identifying or classifying specific categories of mechanisms and the problem of geometry idealization and simplification for certain categories of parts and mechanisms.

Using the example of a Ford® Zetec® engine, where 74 fasteners are present in the assembly, each fastener must first be identified, followed by a lengthy procedure of reducing each fastener to a proxy geometry that can be adequately represented to the analysis code. Each fastener, while similar, requires individual attention requiring in-depth knowledge of a CAD modeling tool, such as Cubit™, to prepare each for analysis. In addition to being time consuming, these bolt reduction procedures can be tedious and error-prone, introducing potential errors into the simulation. In addition, variation in fastener representations chosen by individual analysts may vary considerably based on experience and judgement, introducing additional variability in simulation results.

Complex assemblies frequently include many common mechanisms such as bolts, screws, springs, bearings and so forth. In practice, analysts will spend extensive time identifying and then transforming each mechanism to prepare for analysis. For example, bolted connections may require specific geometric simplifications, specialized meshing and boundary condition assignment. For assemblies with hundreds of bolts, model preparation can be tedious and often error prone. The illustrative embodiments use machine learning methods to rapidly classify CAD parts into categories of mechanisms. Once classified the analyst is able to preview and apply category-specific solutions to quickly transform them to a simulation-ready form.

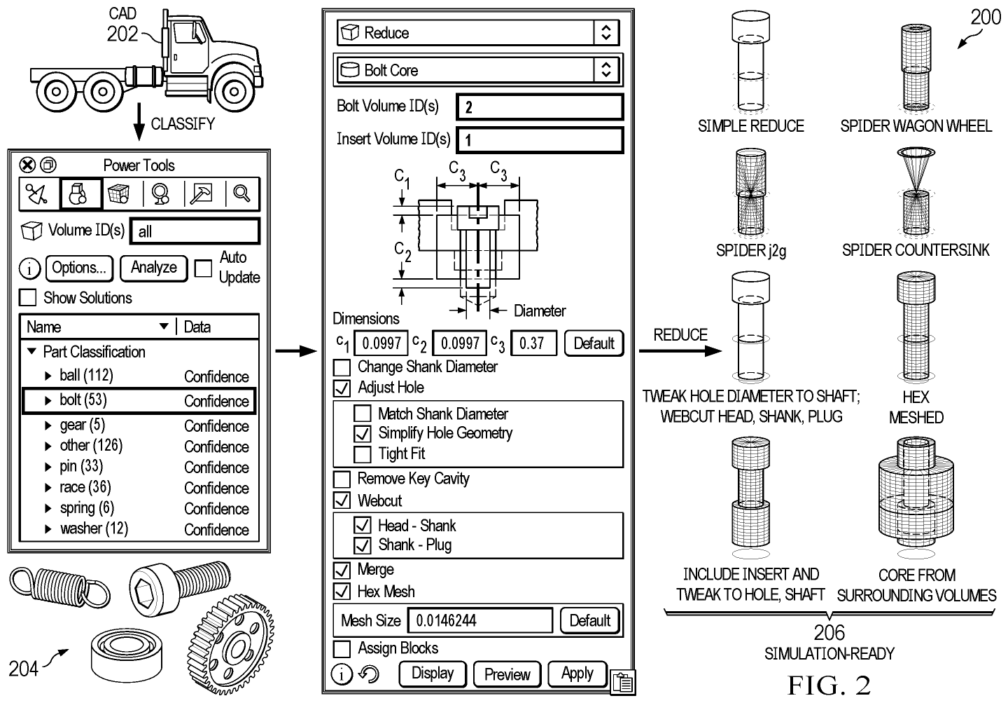

FIG. 2 depicts a diagram illustrating the environment 200 for grouping volumes 204 of a CAD assembly 202 in real time using a classification procedure in accordance with an illustrative embodiment. In this example, volumes classified as bolts can be quickly reduced to a simulation-ready form 206 with a single operation that may include automatic defeaturing, meshing and boundary condition assignment. The user may preview the reduced form from a wide variety of options and apply the reduction operation to multiple bolts at the same time.

While machine learning is widely used in text, image, audio, and video analysis, there has been little research on the application of machine learning to model preparation for simulation.

Supervised machine learning is typically characterized as a problem where, given a training dataset {(x₁, y₁), . . . , (xₙ, yₙ)} with vector input features x and vector output features y (typically referred to as labels or ground-truth), it is assumed that there exists an unknown function y=ƒ(x) that maps input features to output features. Using a learning algorithm, a model can be trained (or fit) to the data, so that the model approximates ƒ. Once a model has been trained, it can be used to evaluate new, previously unseen input vectors to estimate (or predict) the corresponding output vectors. To apply supervised machine learning in a new problem area, the researcher must determine what the domain-specific outputs will be, identify the available domain-specific input features that can be used to predict them, and create a training dataset containing enough examples of each to adequately represent their distributions.

To predict mechanism categories based on a geometric volume requires characterization of the geometry and topology of the CAD part. For each volume G₃ composed of vertices, curves and surfaces, a characteristic feature vector x^{G}₃ is defined. The selected features that characterize G₃ are based upon a fixed-length set of numerical values describing the geometric volume. Attributes are queried from a geometry engine for each volume and used to construct x^{G}₃. In the present example, 48 features were selected based on common characteristics of curves, surfaces and volumes frequently used for mesh generation. These features are listed in Table 1 below. Each feature is easily computed or derived from common query functions of a 3D geometric modeling kernel.

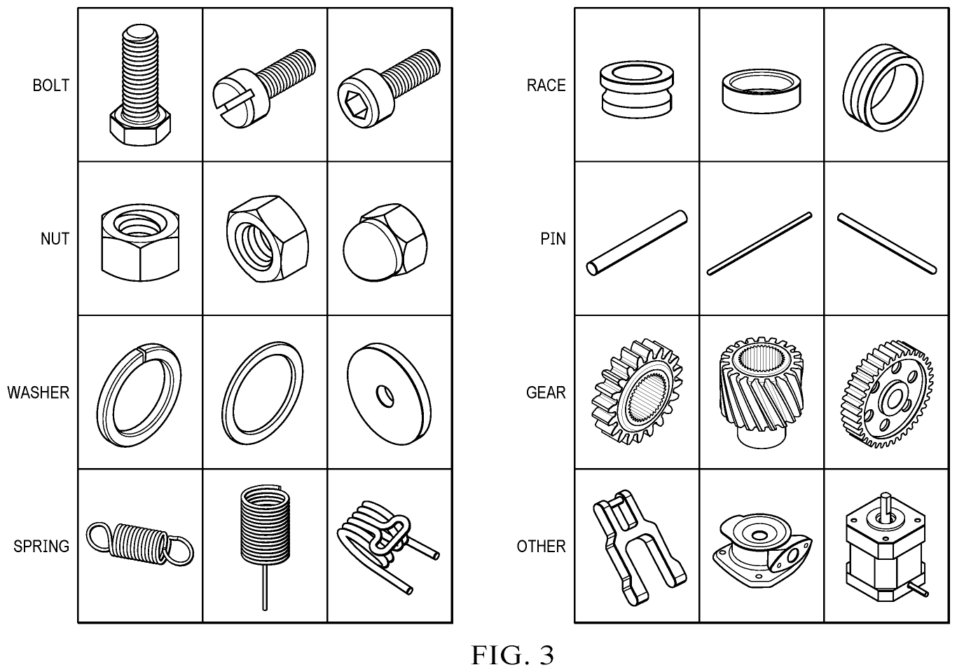

For a supervised machine learning model associated with each volume G₃, a ground truth classification is provided. FIG. 3 illustrates examples of CAD parts used to develop ground truth for mechanism classification in accordance with an illustrative embodiment. This process was performed initially by developing a python script that would read a CAD part and present the operator with an isometric image of the volume. To evaluate our methods, we initially used external sources including GrabCAD, which is a free subscription service that provides a large database of CAD models in a wide variety of formats. Contributions to GrabCAD come from a multiplicity of sources including industrial, aerospace, transportation, animation, and many others.

Selected CAD assemblies were processed by our python script and separated into individual parts. The operator then chose from the predefined set of nine mechanism categories for each CAD part. A feature vector, x^{G}₃ was generated and appended to one of nine .csv files named for its classification category. For example, if the operator identifies the part as a gear, features are computed for the volume and appended to a file named gear.csv. Any CAD kernel with the relevant evaluators can be used.

The illustrative embodiments can employ different machine learning (ML) methods including neural networks and ensembles of decision trees.

Neural Networks (NN) are a class of machine learning methods inspired by the human brain consisting of multiple layers of “neurons” or nodes that activate based on various input criteria. The NN is designed such that the input layer consists of a set of characteristic features, and the final output layer is a resulting predicted value or classification. NN is often applied to image recognition applications where the input features are comprised of a set of intensity or RGB values on a 2D matrix of pixels. The output layer may include a small set of nodes, where for example, the probability of the image depicting a cat or dog is predicted.

A neural network is “trained” by providing multiple instances of features with known outcomes or “labels”. As more training data is provided, floating point values or weights are adjusted at each of the nodes of the NN, so that a set of features with a known label will produce the expected result. An accurate model, once it has been trained, should be able to ingest features not yet encountered and produce a correct predicted outcome or classification. As NN training is a common procedure, many open-source tools are available for managing and training NN models (e.g., PyTorch).

The present application is ideally suited to a traditional classification problem, where the input layer comprises the 48 features in Table 1 computed from the characteristics of the CAD part. The output layer comprises nine nodes representing each of the initial nine classification categories. While various experiments were implemented, we arrived at a single hidden layer using a batch size of 128 which doubled in size between Sigmoid activations to provide the final nine category output. A Sigmoid activation is terminology used in NN to indicate a specific threshold at which a neuron will “fire” or adjust its weight. Each of the nine output nodes is a floating-point value which roughly approximates a probability score of whether the CAD part, represented by the 48 features, can be categorized by one of the nine categories. Each of the nine positions of the output vector correspond to one of the nine categories.

We note that our selection of features was based mostly on intuition, where values considered to be unique to a specific CAD part were computed and used as a feature. The weakness to this approach is that some features may be highly correlated with others. This means that two or more features may be related so that ignoring or dropping one of the features will not affect the predicted outcome appreciably. Techniques for measuring feature correlation have been well established in the ML literature.

For our features, we discovered that many were highly correlated and speculated that feature reduction would reduce the computational time for training. To determine feature correlation, we used the Spearman's correlation coefficient which measures monotonic relationships between features. A stepwise removal of features was conducted by eliminating the feature that had the highest correlation. Single eliminations were done one at a time because of both the small number of features to perform the analysis and because it is possible that removing one highly correlated feature eliminates other correlations within the set until the remaining features had a Spearman's ρ of 0.29 or less.

In the present example, nine features were extracted from the initial 48 features in Table 1 using the above method (indicated by an * in Table 1). This subset of nine features include number of through holes; volume of CAD part/volume tight bounding box; largest moment of inertia; smallest moment of inertia; total area of surfaces with at least one curve having an exterior angle ranging from 0 to 135 degrees/total area; area of surfaces with radius greater than the smallest curve/total area; length of linear curves/length of all curves; total length of curves on the CAD part with exterior angles ranging from 315 to 360 degrees/length of all curves; and total length of curves on the CAD part with exterior angles ranging from 135 to 225 degrees/length of all curves. These features could be described as composite features of the removed features and therefore contained the majority of the information needed to perform the classification.

An ensembles of decisions trees (EDT) model is a collection of individual decision trees, each of which is trained on a subset of the full training data. At evaluation time, the EDT's prediction is a weighted sum of the predictions of each of its individual trees. In prior work, the inventors used a regression EDT to predict mesh quality outcomes based on local geometric features of a CAD model. This work uses a similar approach where we extend EDT to use geometric features for classification.

As noted above, the features developed for the illustrative embodiments have a high level of interdependence or multicollinearity. This aspect appears not to be a problem for EDT, since the model will trim/prune the tree as it randomly selects the best output for the class through a voting process. Even with the full 48 features, training the EDT can be completed in a few seconds on most regular 64 bit systems.

A product of the EDT method is a set of values known as feature importance, that measure the relative significance of each feature in determining the final classification outcome. To identify features that do not appreciably contribute to the final classification outcome, an additional random number feature can be added, which presumably should contribute nothing to the outcome. Features that report a feature importance with less than the feature importance measured for the random number indicate characteristics that do not contribute in an appreciable way to the final classification category.

Upon conducting feature importance analysis, we noted that only two of the 48 features fell below the feature importance of the random number on a consistent basis. This indicates that the EDT model used the majority of all the features to determine classification outcomes. We postulate that this is because not all features are of value in classifying every part or shape. Each shape or geometry may have a unique set of features that applies for the shape, which plays the role of the “label” classification. As the EDT performs its part classification it adds and eliminates features as needed for each item. Rendering the final decision to be the best outcome.

EDT also shows promise in additional applications involving random forrest operations and user developed part classification. One of the goals of adding ML assistance to the operator was to allow for users to define their own parts that may not exist in the current set of parts. The user need only select one or two parts and label the part as desired. The ML models are unloaded then reloaded to add the new part. This reloading results in the random forrest automatically obtaining the features developed from the selected parts and adding them to the list of possible parts. The EDT allows for the user to have access to a new automatic classification of the desired part and to instantaneously retrain the EDT.

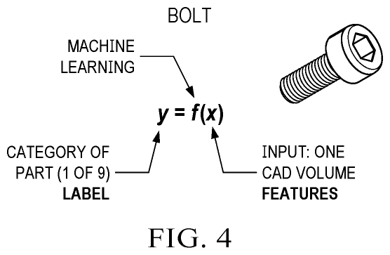

FIG. 4 depicts a diagram illustrating the classification problem solved by the machine learning process in accordance with an illustrative embodiment. The classification problem can be defined by the equation:

$$y = f ( x )$$

where x defines the input of a CAD volume, which is characterized by a set of scalar values representing features. y represents the output, which in the present context is a label for the category of mechanism for the CAD volume to be identified (e.g., bolt). The function ƒ that relates x to y represents the machine learning method.

Both a command line capability and graphical user interface can be implemented with the illustrative embodiments. Both of these implementations can be built upon a new machine learning library accessed via an application programming interface (API) through C++ or python.

Included in the new ML library are functions to generate the standard set of 48 features given a single part CAD model. This process involves querying the CAD kernel to compute each of the 48 features. Once computed, the features can then be used to generate a classification prediction using scikit-learn. While the ML library is developed in C++, as the classification capabilities require access to the python open-source scikit-learn libraries, it was necessary to implement methods that would allow C++ functions to seamlessly call these python routines to execute the classification predictions.

Training a set of CAD parts and generating predictions comprises generating training data by providing a fixed set of .csv files named according to their classification category, where each row of a .csv file contains entries corresponding to the features of one CAD volume (e.g., 48 entries). Standard python tools can be used to import each of the .csv files and store the features and labels as vectors. To execute EDT training, the sklearn Random Forrest Classifier can be invoked direction. Sklearn also allows for optional arguments to permit customization of the decision tree methods. These arguments can be used to control the maximum number of trees and the maximum depth of branching permitted for each individual tree. Once a successful EDT model is generated, it can be placed into a pickle file (serialized), which will encode the model as a byte stream on disk for later use to predict classification categories.

To perform prediction, the serialized EDT model is imported and stored. The user can identify one or mode CAD parts for which a classification category is to be predicted. The features are then computed for each CAD part. As features normally cannot be used directly, a scaling pipeline is first applied to each of the features. Sklearn is invoked, and a result vector of probabilities is returned. The category with the highest probability can be used as the selected classification category. It may also be useful to provide a probability or confidence value to the user.

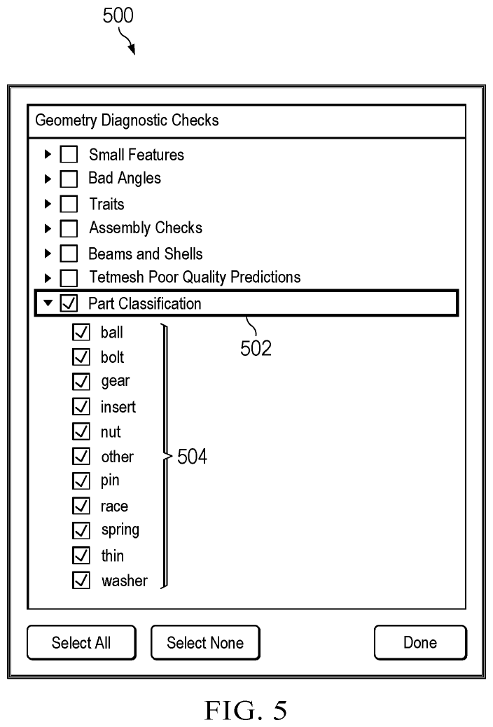

FIG. 5 depicts an example of a graphical user interface with classification options in accordance with an illustrative embodiment. Graphical user interface 500 provides an extension of Geometry Power Tool, which can be implemented with the QT framework. This tool provides diagnostics to assist in geometry cleanup and defeaturing prior to mesh generation.

Graphical user interface 500 adds Part Classification 502 as new diagnostic option. To use the new classification diagnostic, the user selects Part Classification 502 and then selects the desired categories 504.

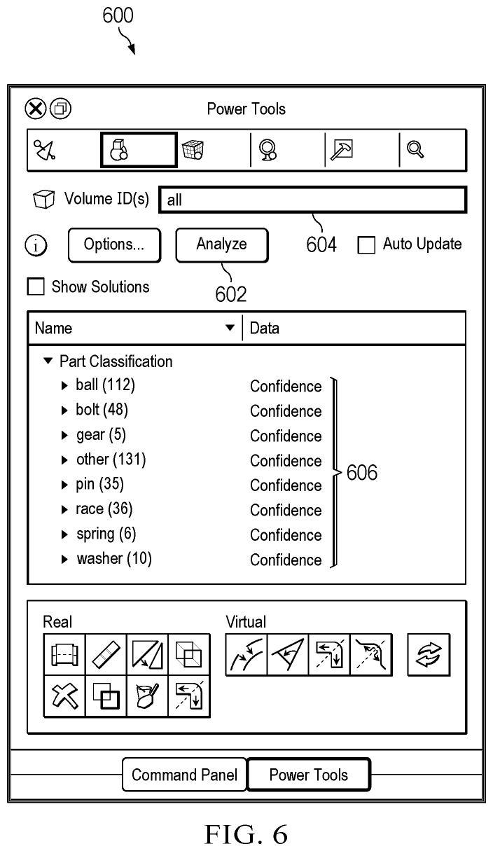

FIG. 6 depicts an example graphical user interface 600 showing classification results in accordance with an illustrative embodiment. When the user selects the Analyze button 602 the ML library is invoked. The Geometry Power Tool will perform classification predictions on all active library volumes indicated in selection field 606 at the top of graphical user interface 600 (in the present example, all volumes). The results are displayed as a categorized list of parts 606.

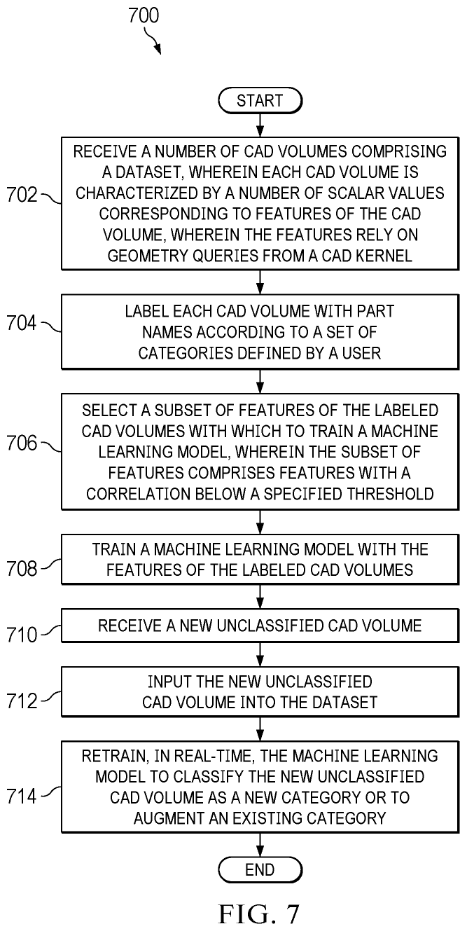

FIG. 7 depicts a flowchart illustrating a process of machine learning classification for Computer Assisted Design (CAD) in accordance with an illustrative embodiment. Process 700 might be implemented with CAD classification system 100 in FIG. 1.

Process 700 begins by receiving a number of CAD volumes comprising a dataset (step 702). Each CAD volume is characterized by a number of scalar values corresponding to features of the CAD volume. The features rely on geometry queries from a CAD kernel.

Process 700 labels each CAD volume with part names according to a set of categories defined by a user (step 704). Process 700 may select a subset of features of the labeled CAD volumes with which to train a machine learning model, wherein the subset of features comprises features with a correlation below a specified threshold (step 706). The correlation used to select the subset of features might comprise a Spearman's coefficient.

Process 700 trains the machine learning model with the features of the labeled CAD volumes (step 708). The machine learning model might comprise ensembles of decision trees or a neural network.

When a new unclassified CAD volume is received (step 710), process 700 inputs the new unclassified CAD volume into the dataset (step 712). Process 700 retrains, in real-time, the machine learning model to classify the new unclassified CAD volume as a new category or to augment an existing category (step 714). Process 700 then ends.

The illustrative embodiments not only identify certain categories of mechanisms commonly encountered in design solid models but also provide simplified methods for rapidly reducing original solid model representations to something that can be used in an analysis with little user interaction. As an exemplar problem, we focused on the fastener reduction problem but also addressed reduction of spring components. Additional mechanism types will be addressed as the need arises.

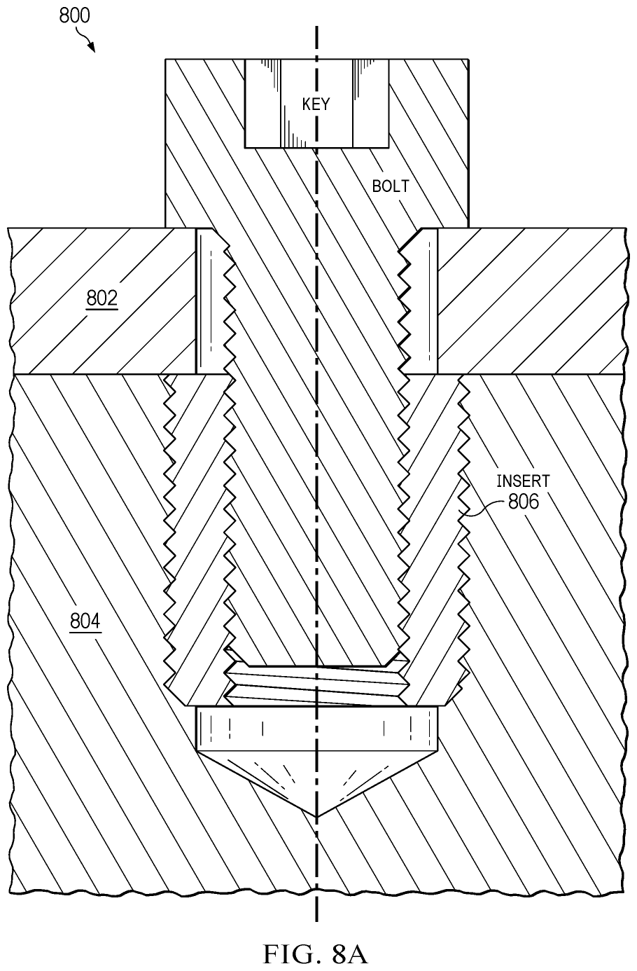

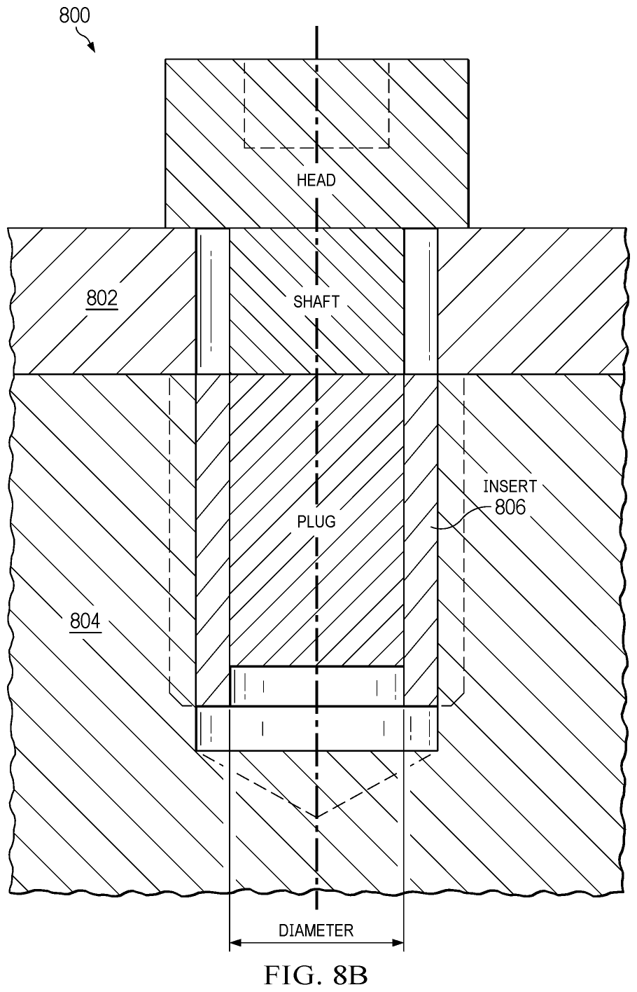

FIGS. 8A and 8B illustrate a process of geometry reduction for a bolt in accordance with an illustrative embodiment. FIG. 8A illustrates an initial bolt solid model in context with its surrounding volumes. FIG. 8B illustrates a reduced bolt geometry ready for analysis. The present example is related to reduction of a fastener, but the process can be applied to other type of mechanisms such as springs, gears, etc.

An experienced analysts may take 30 minutes to an hour to perform and document the procedure for a single fastener (bolt). Scaling this formula to all bolts in an assembly, the process of preparing fasteners for analysis on a complex model could take several weeks, not to mention the tedious and potentially error-prone nature of repeating the same recipe multiple times.

While each of the steps involved can be readily learned by a novice analyst, the user must be precise in each step, as errors or omissions could conceivably have significant consequences to the final analysis. Small differences in engineering judgement in implementing this recipe between analysts can also be a source of error. A user may need to experiment with several variations of the recipe on a single bolt to determine its feasibility, however once a specific set of requirements is established, the user may reduce any number of fasteners in the assembly at the same time, conceivably reducing model preparation time by days and perhaps weeks.

In the example shown in FIG. 8A, a single bolt 800 fastens two volumes 802, 804. An insert or cylinder band 806 is modeled surrounding the shaft of the bolt 800. The user may choose from multiple input options when reducing this fastener such as, e.g., including the insert, adjusting shaft diameter, align axis of the bolt with the bolt hole, tight fit to remove any gaps or overlaps between the bolt geometry and the lower volume, adjusting hole diameter so only the diameter of the hole is adjusted to match the bolt instead of filling gaps, simplifying the hole, removing the key, merging the surfaces between the bolt and its hole so that the elements are contiguous between the bolt and surrounding geometry, webcut to split the bolt into two or three parts (identified as head, shaft, and plug as shown in FIG. 8B), mesh the bolt with hexes, block IDs and names, and preview without actually modifying the bolt and surrounding geometry.

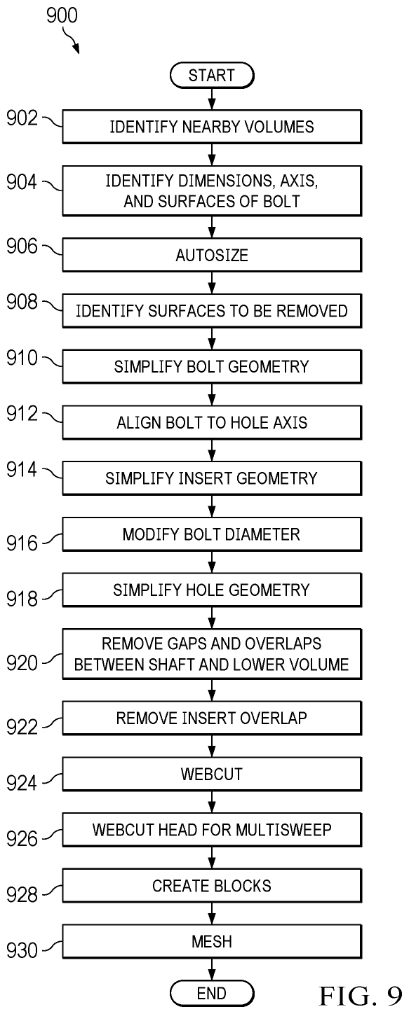

FIG. 9 depicts a flowchart illustrating an algorithm to reduce one or more bolts in accordance with an illustrative embodiment. The input comprises one or more volumes classified as “bolt”. Optional corresponding volumes classified as “insert” may also be specified. The output is a reduced set of bolt and insert geometry, optionally webcut, meshed with boundary conditions applied. Depending upon user options, the neighboring volumes may also be modified.

Process 900 begins by identifying nearby volumes (step 902). This step includes at least one upper volume (e.g., 802) and a lower volume (804). If not already provided by the user, an optional insert volume can also be determined based on proximity.

Process 900 identifies dimensions, axis, and surfaces of the bolt (step 904). This step includes top and bottom surfaces as well as shaft and head. These elements can be extracted based on expected common characteristics of known bolt geometry.

Process 900 computes an autosize (step 906). If a mesh size is not specified by the user, an autosize is computed, which is a mesh size based on the relative dimensions of the bolt volumes. While used for meshing, this value is also used for determining tolerances in diagnostics used in the next step.

Process 900 identifies surfaces to be removed (step 908). Geometric diagnostics are performed to determine whether the bolts' surfaces have certain traits including blends, chamfers, cavities, close loops, small faces or conical surfaces.

Process 900 Simplifies bolt geometry (step 910). Successive CAD operations to remove the surfaces identified in step 908 are performed. Removal of a surface of one trait characteristic may introduce other surfaces that require removal. As a result, steps 908 and 910 can be repeated until no further surface removal operations are possible.

Process 900 aligns the bolt to the hole axis (step 912). If the align bolt option is used, check for alignment of the hole and bolt axis. If it is not properly aligned, transform the bolt geometry to match the hole.

Process 900 simplifies insert geometry (step 914). If an insert is present, the procedure described in steps 908 and 910 can be used to simplify the insert geometry.

Process 900 modifies bolt diameter (step 916). If a diameter value is specified in the command, a CAD surface offset operation can adjust the diameter of the bolt shaft.

Process 900 simplifies hole geometry (step 918). If the simplify hole option is used, any chamfers or rounds decorating the hole geometry are identifies as well as any conical surfaces as the bottom of the hole. These surfaces are also removed.

Process 900 removes gaps and overlaps between shaft and lower volume (920). If the tight fit option is used, the hole surfaces from the lower volume are identified and removed. A boolean subtract operation is then performed between the lower volume and the overlapping portion of the bolt shaft geometry. This will leave the shaft and lower volume exactly matching, eliminating any gaps or overlaps. Note that this option is not valid if an insert geometry is present.

Process 900 removes insert overlap (step 922). If an insert is present, its geometry may overlap the lower volume and potentially the bolt shaft. A Boolean subtract operation can remove material from the insert volume to eliminate any overlap.

Process 900 performs webcut (step 924). If the webcut option is used, the head will be cut from the shaft by using a sheet extended from the base of the bolt head. Separating the shaft from the plug is done by web-cutting using a sheet extended from the top surface of the lower volume. A merge operation is done between the three bolt components to ensure a contiguous mesh will be generated (see FIG. 8B).

Process 900 webcuts the head for multisweep (step 926). If the key cavity remains in the bolt geometry, and the mesh option is used, process 900 will attempt to webcut the bolt head using the cylindrical surface extended from the bolt shaft, which facilitates use of a pave-sweep many-to-one tool. Where the cavity remains in the bolt, more than one target surface would be required.

Process 900 creates blocks (step 928). Blocks are created for each bolt component and insert (if present) and named/numbered according to the user input options. Where multiple bolts are reduced in the same command, the user can specify consecutive numbering conventions so that, for instance, all bolt heads have the same block ID, or alternatively, each successive bolt head gets assigned an incremented block ID number.

Process 900 then meshes (step 930). In this step an autoscheme tool is invoked and uses the input mesh size (or autosize computed in step 906), followed by the pave and sweep tools to generate a hex mesh on each of the bolt components as well as the insert, if present. Mesh quality is also checked following meshing, and potential element quality issues are reported to the user.

Process 900 then ends.

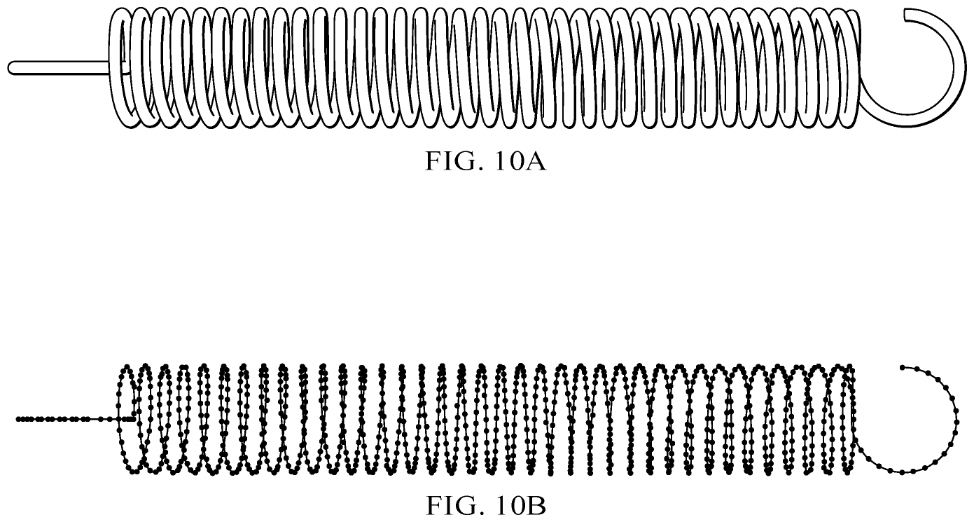

FIGS. 10A and 10B illustrate a process of geometry reduction for a spring in accordance with an illustrative embodiment. FIG. 10A illustrates an initial spring solid model. FIG. 10B illustrates a reduced, beam representation of the spring ready for analysis.

Preparing springs for analysis is another challenging process. In this case, a full 3D solid representation of the spring would require enormous numbers of hexes or test to accurately model the physics. Instead, a dimensionally reduced version of the spring is usually used in the analysis. To accurately model and prepare a spring for analysis, such as FIG. 10A, an experienced analysts may take several hours to days. The illustrative embodiments target some of the most time consuming aspects of preparing a spring for analysis. Similar to the reduce bolt command, the reduce spring command can reduce multiple springs with a single operation.

The user may choose from multiple input options when reducing the spring such as, e.g., combine, mesh, mesh size, block IDs and name, and preview. Combine generates multiple curves based on the initial surface geometry of the spring. This may result in small curves being generated that affect mesh quality. The combine option will combine the individual curves into a single curve. Mesh generates a set of beam elements along the curves, and mesh size specifies the target length of the beam elements. Block IDs and name specify block names and/or IDs for the spring(s). Preview shows the user a preview of the reduction with the specified options without actually modifying the spring.

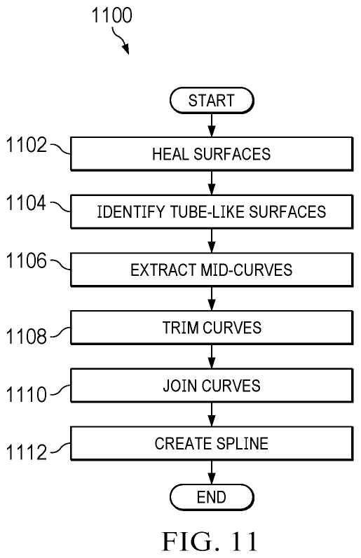

FIG. 11 depicts a flowchart illustrating an algorithm to reduce one or more springs in accordance with an illustrative embodiment. The input comprises one or more volumes classified as “spring”. The output is one or more connected spline curves following the mid-curve of the spring (see FIG. 10B). The output might be optionally meshed with beam elements.

Process 1100 begins by healing surfaces (step 1102). This step checks for parts that have blends or surfaces that can be split into parts and merges tangent surfaces together to assist the generating tube-like surfaces.

Process 1100 then identifies tube-like surfaces (step 1104). This step identifies surfaces of type cylinder, tori, NURBS (non-uniform rational basis spline) with circular cross-section, and helical sweeps that sweep a circle along a helix.

Process 1100 extracts mid-curves (step 1106). From each surface identified in step 1104, step 1106 extracts the curve at the middle of the cross-section defining the trajectory of the surface.

Process 1100 then trims the curves (step 1108). This step identifies capping surfaces and trims mid-curves with caps. If requested, process 1100 joins the mid-curves into a single wire body (step 1110).

Process 1100 then creates a spline (step 1112). If a single curve is desired, step 1112 fits all mid-curves to a single NURBs curve.

Process 1100 then ends.

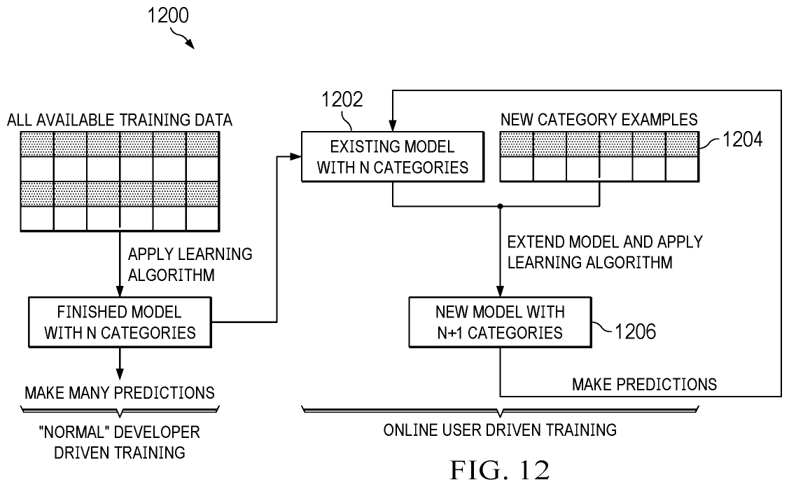

FIG. 12 depicts a diagram of a schema for in-situ classification in accordance with an illustrative embodiment. With the classification prediction procedures described above, the “normal” developer training scenario depends on gathering many examples of CAD parts that are representative of the initial categories. The developer will then assign ground truth or labels to each CAD part; features will then be computed and written to a .csv file. At some point, when the developer feels there is a representative sample, the model can be trained using the sklearn EDT functions in a separate python script, and a serialized snapshot of the resulting model written to a pickle file. To execute a prediction, using the “Normal” developer driven training, the pickled model is loaded once upon invoking the ML tools. Each requested prediction will then use the static unpickled model to invoke sklearn to discern a classification from the initial set of categories.

Schema 1200 allows the user to dynamically add additional classification categories from within the CAD tool. The initial categories selected for ground truth are based on discussion with analysts, but primarily rely on researcher's intuition as to what names and categories would be most useful. In a National Laboratory setting, particularly in proprietary or more restrictive environments, developer-defined categories will undoubtedly not envision all potential categories of parts that will be needed.

Schema 1200 allows the user to add additional ground truth to their training models. This process may include adding additional training data to existing categories or to newly defined user categories. This requires that the new models be persistent between runs of the software. Users can share user training data so that models can progressively become more accurate and relevant for a given application or physics domain based on models encountered.

Users can modify the classification assignment. In cases where a user defines a new category which may refine or change the intended classification, it may be necessary to change the ground truth for some CAD parts. The user can update the EDT classification model on demand. Any time a new ground truth is defined by the user or reclassification is necessary, the EDT model will no longer be up to date. As a consequence, a mechanism should be provided for timely automatic updates or retraining from within the CAD software.

FIG. 12 outlines the scenario for online user-driven training. Starting from the existing model 1202 provided by the developer, users provide unique examples to establish a new category 1204. Learning algorithms are then reapplied to both the existing model and the additional user data, creating a new extended model 1206 that incorporates both developer-driven and user data. Subsequent predictions can now be made based on the extended model.

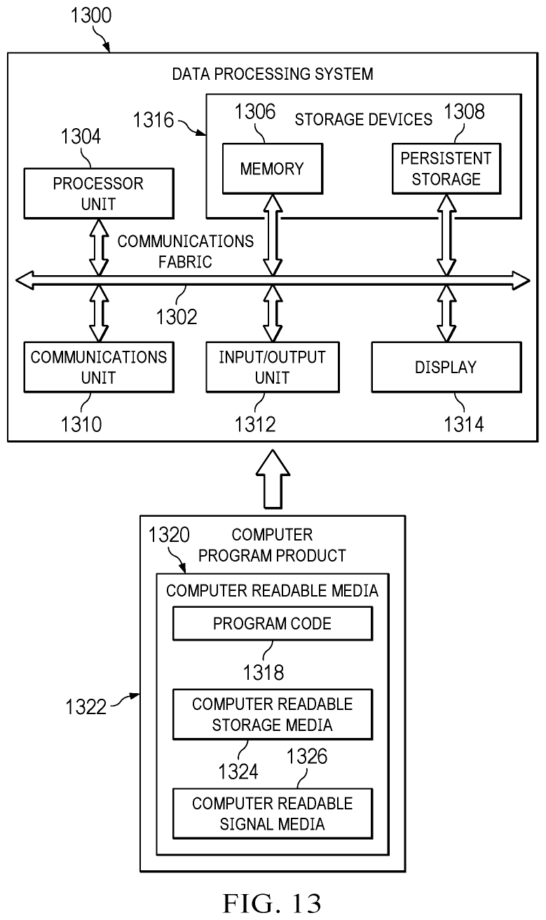

Turning to FIG. 13, a diagram of a data processing system is depicted in accordance with an illustrative embodiment. Data processing system 1300 is an example of a system in which computer-readable program code or program instructions implementing processes of illustrative embodiments may be run. Data processing system 1300 may be used to implement CAD classification system 100 in FIG. 1. Turning now to FIG. 13, an illustration of a block diagram of a data processing system is depicted in accordance with an illustrative embodiment. Data processing system 1300 may be used to implement computer system 150 in FIG. 1. In this illustrative example, data processing system 1300 includes communications fabric 1302, which provides communications between processor unit 1304, memory 1306, persistent storage 1308, communications unit 1310, input/output unit 1312, and display 1314. In this example, communications fabric 1302 may take the form of a bus system.

Processor unit 1304 serves to execute instructions for software that may be loaded into memory 1306. Processor unit 1304 may be a number of processors, a multi-processor core, or some other type of processor, depending on the particular implementation. In an embodiment, processor unit 1304 comprises one or more conventional general-purpose central processing units (CPUs). In an alternate embodiment, processor unit 1304 comprises one or more graphical processing units (GPUs).

Memory 1306 and persistent storage 1308 are examples of storage devices 1316. A storage device is any piece of hardware that is capable of storing information, such as, for example, without limitation, at least one of data, program code in functional form, or other suitable information either on a temporary basis, a permanent basis, or both on a temporary basis and a permanent basis. Storage devices 1316 may also be referred to as computer-readable storage devices in these illustrative examples. Memory 1306, in these examples, may be, for example, a random access memory or any other suitable volatile or non-volatile storage device. Persistent storage 1308 may take various forms, depending on the particular implementation.

For example, persistent storage 1308 may contain one or more components or devices. For example, persistent storage 1308 may be a hard drive, a flash memory, a rewritable optical disk, a rewritable magnetic tape, or some combination of the above. The media used by persistent storage 1308 also may be removable. For example, a removable hard drive may be used for persistent storage 1308. Communications unit 1310, in these illustrative examples, provides for communications with other data processing systems or devices. In these illustrative examples, communications unit 1310 is a network interface card.

Input/output unit 1312 allows for input and output of data with other devices that may be connected to data processing system 1300. For example, input/output unit 1312 may provide a connection for user input through at least one of a keyboard, a mouse, or some other suitable input device. Further, input/output unit 1312 may send output to a printer. Display 1314 provides a mechanism to display information to a user.

Instructions for at least one of the operating system, applications, or programs may be located in storage devices 1316, which are in communication with processor unit 1304 through communications fabric 1302. The processes of the different embodiments may be performed by processor unit 1304 using computer-implemented instructions, which may be located in a memory, such as memory 1306.

These instructions are referred to as program code, computer-usable program code, or computer-readable program code that may be read and executed by a processor in processor unit 1304. The program code in the different embodiments may be embodied on different physical or computer-readable storage media, such as memory 1306 or persistent storage 1308.

Program code 1318 is located in a functional form on computer-readable media 1320 that is selectively removable and may be loaded onto or transferred to data processing system 1300 for execution by processor unit 1304. Program code 1318 and computer-readable media 1320 form computer program product 1322 in these illustrative examples. In one example, computer-readable media 1320 may be computer-readable storage media 1324 or computer-readable signal media 1326.

In these illustrative examples, computer-readable storage media 1324 is a physical or tangible storage device used to store program code 1318 rather than a medium that propagates or transmits program code 1318. Computer readable storage media 1324, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Alternatively, program code 1318 may be transferred to data processing system 1300 using computer-readable signal media 1326. Computer-readable signal media 1326 may be, for example, a propagated data signal containing program code 1318. For example, computer-readable signal media 1326 may be at least one of an electromagnetic signal, an optical signal, or any other suitable type of signal. These signals may be transmitted over at least one of communications links, such as wireless communications links, optical fiber cable, coaxial cable, a wire, or any other suitable type of communications link.

The different components illustrated for data processing system 1300 are not meant to provide architectural limitations to the manner in which different embodiments may be implemented. The different illustrative embodiments may be implemented in a data processing system including components in addition to or in place of those illustrated for data processing system 1300. Other components shown in FIG. 13 can be varied from the illustrative examples shown. The different embodiments may be implemented using any hardware device or system capable of running program code 1318.

TABLE 1

| ID | Feature | Description |
|---|---|---|
| 0 | genus* | number of through holes |
| 1 | min_aspect | tight bbox (smallest enclosing box that can fully contain a given |
| | | object, with the box aligned to best fit the object's dimensions) |
| | | minimum length/width ratio |
| 2 | max_aspect | tight bbox maximum length/width ratio |
| 3 | volume_bbox_ratio* | volume of CAD part/volume tight bbox |
| 4 | principal_moments[0]* | principal moment of inertia (a scalar value that quantifies how |
| | | an object's mass is distributed relative to a particular axis of |
| | | rotation) of CAD part (largest) |
| 5 | principal_moments[1] | moment of inertia (second largest) |
| 6 | principal_moments[2]* | smallest moment of inertia |
| 7 | dist_centroid_to_bbox_ctr | Distance from vol. centroid (3-dimensional vector representing |
| | | geometric centroid of CAD part) to tight bbox centroid (3- |
| | | dimensional vector representing centroid of the tight bounding box) |
| 8 | mesh_size_ratio | mesh auto size = 5.0 (mesh auto size, based on Cubit's internal |
| | | algorithm, automatically sets mesh resolution according to an |
| | | object's size and geometry. The scalar value ranges from 1.0 |
| | | (coarse) to 10.0 (fine))/tight bbox diagonal (largest diagonal |
| | | distance between corners of the tight bounding box) |
| 9 | min_area_ratio | min. surf. area (smallest surface area of any topological surface |
| | | on the CAD part)/tot. surf. area (sum of the surface area for all |
| | | topological surfaces on the CAD part) |
| 10 | max_area_ratio | max. surf. area (largest surface area for any topological surface |
| | | on the CAD part)/tot. surf. area |
| 11 | avg_area_ratio | average surf. area (average surface area over all topological |
| | | surfaces on the CAD part)/tot surf. area |
| 12 | area_vol_ratio | tot. surf. area * bbox. diagonal/volume (geometric volume of the |
| | | CAD part) |
| 13 | bbox_area_vol_ratio | tot. surf. area/bbox. area (from tight bounding box dimensions |
| | | (l, w, h) bbox area = 2*l*w + 2*w*h + 2*h*l) |
| 14 | area_ratio_cylinders | area cylinder surfs. (sum of area of all planar topological |
| | | surfaces in the CAD part)/tot. area |
| 15 | area_ratio_planar | area planar surfs. (sum of area of all planar topological surfaces |
| | | in the CAD part)/tot. area |
| 16 | area_ratio_blend | area blend surfs. (sum of area of all topological surfaces |
| | | identified as blends: a transition surface between two or more |
| | | adjacent surfaces or edges, such as a fillet)/tot. area |
| 17 | area_ratio_periodic | area periodic surfs. (sum of area of all topological surfaces |
| | | identified as periodic: repeats a basic shape, called a |
| | | “fundamental region,” in one or two directions to create the |
| | | entire surface)/tot. area |
| 18 | area_ratio_facet | area facet surfs. (sum of area of non-planar surfaces represented |
| | | solely by discrete triangular elements)/tot. area |
| 19 | area_ratio_end | area surfs w/curves 225° > θ > 360° (total area of surfaces with at |
| | | least one curve having an exterior angle ranging from 225 to 360 |
| | | degrees)/tot. area |
| 20 | area_ratio_interior* | area surfs w/curves 0° > θ > 135° (total area of surfaces with at |
| | | least one curve having an exterior angle ranging from 0 to 135 |
| | | degrees)/tot. area |
| 21 | area_ratio_side | area surfs w/curves 135° > θ > 225° (total area of surfaces with at |
| | | least one curve having an exterior angle ranging from 135 to 225 |
| | | degrees)/tot. area |
| 22 | area_ratio_mixed | area surfs with more than one category crv. (total area of surfaces |
| | | that fit into more than one of the categories area_ratio_side, |
| | | area_ratio_interior and area_ratio_end)/tot. area |
| 23 | area_ratio_no_curvature | area surfs with no curvature (planar) (total area of surfaces that |
| | | have no curvature: radius of curvature is infinite)/tot. area |
| 24 | area_ratio_low_curvature | area surfs. with rad. (radius of curvature) > 100 * small_curve |
| | | (user-defined length typically set as the smallest significant size |
| | | for finite element analysis, commonly defaulted to 25% of the |
| | | target mesh size)/tot. area |
| 25 | area_ratio_medium_curvature | area surfs. with rad. > 10 * small_curve/tot area |
| 26 | area_ratio_high_curvature* | area surfs. with rad. > small_curve/tot. area |
| 27 | curve_length | len. all curves (total length of all topological curves in the CAD |
| | | part)/bbox. diagonal |
| 28 | curve_to_area_ratio | len. all curves * bbox. diagonal/tot. area |
| 29 | min_length_ratio | min. curve len. (shortest length among all topological curves in |
| | | the CAD part)/len. all curves |
| 30 | max_length_ratio | max. curve len. (longest length among all topological curves in |
| | | the CAD part)/len. all curves |
| 31 | avg_length_ratio | avg. curve len. (average length of all topological curves in the |
| | | CAD part)/len. all curves |
| 32 | length_straight_ratio* | len. linear curves (curves that are straight)/len. all curves |
| 33 | length_arcs_ratio | len. arc curves (curves with constant curvature, forming part of a |
| | | circle)/len. all curves |
| 34 | length_parabola_ratio | len. parabola curves (a U-shaped curve where any point is at an |
| | | equal distance from a fixed point (the focus) and a fixed line |
| | | (the directrix))/len. all curves |
| 35 | length_helix_ratio | len. helix curves (a spiral-shaped curve that wraps around a |
| | | cylinder or cone)/len. all curves |
| 36 | length_spline_ratio | len. spline curves (a smooth, flexible curve that is defined by |
| | | a set of control points)/len. all curves |
| 37 | length_segmented_ratio | len. segmented curves (a curve composed of multiple connected |
| | | segments, each of which are a straight line)/len. all curves |
| 38 | reversal_angles_ratio* | len. curves w/ext. 315° > θ > 360° (total length of curves on the CAD part |
| | | with exterior angles ranging from 315 to 360 degrees)/len. all curves |
| 39 | corner_angles_ratio | len. curves w/ext. 225° > θ > 315° (total length of curves on the CAD part |
| | | with exterior angles ranging from 225 to 315 degrees)/len. all curves |
| 40 | side_angles_ratio* | len. curves w/ext. 135° > θ > 225° (total length of curves on the CAD part |
| | | with exterior angles ranging from 135 to 225 degrees)/len. all curves |
| 41 | end_angles_ratio | len. curves w/ext. 0° > θ > 135° (total length of curves on the CAD part |
| | | with exterior angles ranging from 0 to 135 degrees)/len. all curves |
| 42 | min_dist_to_centroid | min. dist. from centroid to any vertex (shortest distance from the |
| | | CAD part's geometric centroid to any vertex)/bbox. diagonal |
| 43 | max_dist_to_centroid | max. dist. from centroid to any vertex (longest distance from the |
| | | CAD part's geometric centroid to any vertex)/bbox. diagonal |
| 44 | avg_dist_to_centroid | avg. dist. from centroid to any vertex (average distance from the |
| | | CAD part's geometric centroid to all vertices)/bbox. diagonal |
| 45 | min_dist_to_bbox_ctr | min. dist. from bbox. center to any vertex (shortest distance from the |
| | | tight bounding box's center to any vertex in the CAD part)/bbox. diagonal |
| 46 | max_dist_to_bbox_ctr | max. dist. from bbox. center to any vertex (longest distance from the |
| | | tight bounding box's center to any vertex in the CAD part)/bbox. diagonal |
| 47 | avg_dist_to_bbox_ctr | avg. dist. from bbox. center to any vertex (average distance from the |
| | | tight bounding box's center to all vertices in the CAD part)/bbox. diagonal |

As used herein, the phrase “a number” means one or more. The phrase “at least one of”, when used with a list of items, means different combinations of one or more of the listed items may be used, and only one of each item in the list may be needed. In other words, “at least one of” means any combination of items and number of items may be used from the list, but not all of the items in the list are required. The item may be a particular object, a thing, or a category.

For example, without limitation, “at least one of item A, item B, or item C” may include item A, item A and item B, or item C. This example also may include item A, item B, and item C or item B and item C. Of course, any combinations of these items may be present. In some illustrative examples, “at least one of” may be, for example, without limitation, two of item A; one of item B; and ten of item C; four of item B and seven of item C; or other suitable combinations.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks may be implemented as program code.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

What is claimed is:

1. A computer-implemented method of machine learning classification for Computer Assisted Design (CAD), the method comprising:
receiving a number of CAD volumes comprising a dataset, wherein each CAD volume is characterized by a number of scalar values corresponding to features of the CAD volume, wherein the features rely on geometry queries from a CAD kernel;
labeling each CAD volume with part names according to a set of categories defined by a user; and
training a machine learning model with the features of the labeled CAD volumes.

2. The method of claim 1, further comprising:
receiving a new unclassified CAD volume;
inputting the new unclassified CAD volume into the dataset; and
retraining, in real-time, the machine learning model to classify the new unclassified CAD volume as a new category or to augment an existing category.

3. The method of claim 1, wherein the features of the CAD volume comprise:
number of through holes;
tight bounding box minimum length/width ratio;
tight bounding box maximum length/width ratio;
volume of CAD part/volume tight bounding box;
largest moment of inertia;
second largest moment of inertia;
smallest moment of inertia;
distance from volume centroid to tight bounding box centroid;
mesh auto size/tight bounding box diagonal;
minimum surface area/total surface area;
maximum surface area/total surface area;
average surface area/total surface area;
total surface area*bounding box diagonal/volume;
total surface area/bounding box area;
sum of area of all cylinder surfaces/bounding box area;
sum of area of all planar surfaces/total area;
sum of area of all blend surfaces/total area;
sum of area of all periodic surfaces/total area;
sum of area of all facet surfaces/total area;
total area of surfaces with at least one curve having an exterior angle ranging from 225 to 360 degrees/total area;
total area of surfaces with at least one curve having an exterior angle ranging from 0 to 135 degrees/total area;
total area of surfaces with at least one curve having an exterior angle ranging from 135 to 225 degrees/total area;
total area of surfaces that fit into more than one of the above three categories of features/total area;
total area of surfaces that have no curvature/total area;
area of surfaces with radius curvature >100*smallest curve/total area;
area of surfaces with radius curvature >10*smallest curve/total area;
area of surfaces with radius >the smallest curve/total area;
length of all curves/bounding box diagonal;
length of all curves*bounding box diagonal/total area;
shortest curve length/length of all curves;
longest curve length/length of all curves;
average curve length/length of all curves;
length of linear curves/length of all curves;
length of curves with constant curvature/length of all curves;
length of parabola curves/length of all curves;
length of helix curves/length of all curves;
length of spline curves/length of all curves;
length of segmented curves/length of all curves;
total length of curves on the CAD part with exterior angles ranging from 315 to 360 degrees/length of all curves;
total length of curves on the CAD part with exterior angles ranging from 225 to 315 degrees/length of all curves;
total length of curves on the CAD part with exterior angles ranging from 135 to 225 degrees/length of all curves;
total length of curves on the CAD part with exterior angles ranging from 0 to 135 degrees/length of all curves;
shortest distance from centroid to any vertex/bounding box diagonal;
longest distance from centroid to any vertex/bounding box diagonal;
average distance from centroid to any vertex/bounding box diagonal;
shortest distance from bounding box center to any vertex/bounding box diagonal;
longest distance from bounding box center to any vertex/bounding box diagonal; and
average distance from bounding box center to any vertex/bounding box diagonal.

4. The method of claim 3, further comprising selecting a subset of features of the labeled CAD volumes with which to train the machine learning model, wherein the subset of features comprises features with a correlation below a specified threshold.

5. The method of claim 4, wherein the subset of features of the CAD volume include:
number of through holes;
volume of CAD part/volume tight bounding box;
largest moment of inertia; smallest moment of inertia;
total area of surfaces with at least one curve having an exterior angle ranging from 0 to 135 degrees/total area;
area of surfaces with radius >smallest curve/total area;
length of linear curves/length of all curves;
total length of curves on the CAD part with exterior angles ranging from 315 to 360 degrees/length of all curves; and
total length of curves on the CAD part with exterior angles ranging from 135 to 225 degrees/length of all curves.

6. The method of claim 4, wherein the correlation used to select the subset of features comprises a Spearman's coefficient.

7. The method of claim 1, wherein the machine learning model comprises one of:
ensembles of decision trees; or
a neural network.

8. The method of claim 1, wherein the features of each CAD volume are represented by a feature vector, wherein each feature is a dimension of the feature vector.

9. The method of claim 1, further comprising reducing the CAD volumes to constituent geometric components.

10. A system for machine learning classification for Computer Assisted Design (CAD), the system comprising:
a storage device that stores program instructions;
one or more processors operably connected to the storage device and configured to execute the program instructions to cause the system to:
receive a number of CAD volumes comprising a dataset, wherein each CAD volume is characterized by a number of scalar values corresponding to features of the CAD volume, wherein the features rely on geometry queries from a CAD kernel;
label each CAD volume with part names according to a set of categories defined by a user; and
train a machine learning model with the features of the labeled CAD volumes.

11. The system of claim 10, wherein the processors further cause the system to:
receive a new unclassified CAD volume;
input the new unclassified CAD volume into the dataset; and
retrain, in real-time, the machine learning model to classify the new unclassified CAD volume as a new category or to augment an existing category.

12. The system of claim 10, wherein the features of the CAD volume comprise:
number of through holes;
tight bounding box minimum length/width ratio;
tight bounding box maximum length/width ratio;
volume of CAD part/volume tight bounding box;
largest moment of inertia;
second largest moment of inertia;
smallest moment of inertia;
distance from volume centroid to tight bounding box centroid;
mesh auto size/tight bounding box diagonal;
minimum surface area/total surface area;
maximum surface area/total surface area;
average surface area/total surface area;
total surface area*bounding box diagonal/volume;
total surface area/bounding box area;
sum of area of all cylinder surfaces/bounding box area;
sum of area of all planar surfaces/total area;
sum of area of all blend surfaces/total area;
sum of area of all periodic surfaces/total area;
sum of area of all facet surfaces/total area;
total area of surfaces with at least one curve having an exterior angle ranging from 225 to 360 degrees/total area;
total area of surfaces with at least one curve having an exterior angle ranging from 0 to 135 degrees/total area;
total area of surfaces with at least one curve having an exterior angle ranging from 135 to 225 degrees/total area;
total area of surfaces that fit into more than one of the above three categories of features/total area;
total area of surfaces that have no curvature/total area;
area of surfaces with radius curvature >100*smallest curve/total area;
area of surfaces with radius curvature >10*smallest curve/total area;
area of surfaces with radius >the smallest curve/total area;
length of all curves/bounding box diagonal;
length of all curves*bounding box diagonal/total area;
shortest curve length/length of all curves;
longest curve length/length of all curves;
average curve length/length of all curves;
length of linear curves/length of all curves;
length of curves with constant curvature/length of all curves;
length of parabola curves/length of all curves;
length of helix curves/length of all curves;
length of spline curves/length of all curves;
length of segmented curves/length of all curves;
total length of curves on the CAD part with exterior angles ranging from 315 to 360 degrees/length of all curves;
total length of curves on the CAD part with exterior angles ranging from 225 to 315 degrees/length of all curves;
total length of curves on the CAD part with exterior angles ranging from 135 to 225 degrees/length of all curves;
total length of curves on the CAD part with exterior angles ranging from 0 to 135 degrees/length of all curves;
shortest distance from centroid to any vertex/bounding box diagonal;
longest distance from centroid to any vertex/bounding box diagonal;
average distance from centroid to any vertex/bounding box diagonal;
shortest distance from bounding box center to any vertex/bounding box diagonal;
longest distance from bounding box center to any vertex/bounding box diagonal; and
average distance from bounding box center to any vertex/bounding box diagonal.

13. The system of claim 12, further comprising selecting a subset of features of the labeled CAD volumes with which to train the machine learning model, wherein the subset of features comprises features with a correlation below a specified threshold.

14. The system of claim 13, wherein the subset of features of the CAD volume include:
number of through holes;
volume of CAD part/volume tight bounding box;
largest moment of inertia; smallest moment of inertia;
total area of surfaces with at least one curve having an exterior angle ranging from 0 to 135 degrees/total area;
area of surfaces with radius >smallest curve/total area;
length of linear curves/length of all curves;
total length of curves on the CAD part with exterior angles ranging from 315 to 360 degrees/length of all curves; and
total length of curves on the CAD part with exterior angles ranging from 135 to 225 degrees/length of all curves.

15. The system of claim 13, wherein the correlation used to select the subset of features comprises a Spearman's coefficient.

16. The system of claim 10, wherein the machine learning model comprises one of:
ensembles of decision trees; or
a neural network.

17. The system of claim 10, wherein the features of each CAD volume are represented by a feature vector, wherein each feature is a dimension of the feature vector.

18. The method of claim 10, wherein the CAD volumes are reduced to constituent geometric components.

19. A computer program product for machine learning classification for Computer Assisted Design (CAD), the computer program product comprising:
a computer-readable storage medium having program instructions embodied thereon to perform the steps of:
receiving a number of CAD volumes comprising a dataset, wherein each CAD volume is characterized by a number of scalar values corresponding to features of the CAD volume, wherein the features rely on geometry queries from a CAD kernel;
labeling each CAD volume with part names according to a set of categories defined by a user; and
training a machine learning model with the features of the labeled CAD volumes.

20. The computer program product of claim 19, further comprising instructions for:
receiving a new unclassified CAD volume;
inputting the new unclassified CAD volume into the dataset; and
retraining, in real-time, the machine learning model to classify the new unclassified CAD volume as a new category or to augment an existing category.
